(19) United States
(12) Patent Application Publication
(10) Pub. No.: US 2025/0029950 A1
(43) Pub. Date: Jan. 23, 2025

(54) BONDING METHOD AND BONDING SYSTEM

(71) Applicant: Tokyo Electron Limited, Tokyo (JP)

(72) Inventors: Yuji MIMURA, Koshi City (JP); Takashi UNO, Koshi City (JP); Takahiro NODA, Kikuchi-gun (JP); Satoshi MICHINAKA, Kikuchi-gun (JP)

(73) Assignee: Tokyo Electron Limited, Tokyo (JP)

(21) Appl. No.: 18/778,186

(22) Filed: Jul. 19, 2024

(30) Foreign Application Priority Data
Jul. 20, 2023 (JP) 2023-118014

(51) Int. Cl. H01L 23/00

(52) U.S. Cl. CPC H01L 24/80; H01L 24/74; H01L 24/94; H01L 2224/74; H01L 2224/80009; H01L 2224/80895; H01L 2224/80948; H01L 2224/94; H01L 2924/40

(57) ABSTRACT

A bonding method includes: preparing a first semiconductor substrate having a first surface and a second semiconductor substrate having a second surface; hydrophilizing the first surface of the first semiconductor substrate and the second surface of the second semiconductor substrate; bonding the first surface of the first semiconductor substrate and the second surface of the second semiconductor substrate after the hydrophilizing; and bonding the first surface of the first semiconductor substrate and the second surface of the second semiconductor substrate after the hydrophilizing. The enhancing of the bonding strength includes performing heat treatment on the first semiconductor substrate and the second semiconductor substrate in a first temperature range; and performing heat treatment on the first semiconductor substrate and the second semiconductor substrate at a target temperature after the performing of the heat treatment in the first temperature range. The first temperature range is lower than the target temperature.

### CROSS-REFERENCE TO RELATED APPLICATION

This application claims the benefit of Japanese Patent Application No. 2023-118014 filed on Jul. 20, 2023, the entire disclosure of which is incorporated herein by reference.

### TECHNICAL FIELD

The exemplary embodiments described herein pertain generally to a bonding method and a bonding system.

### BACKGROUND

There is known a technique of temporarily bonding two semiconductor wafers and

performing heat treatment on the bonded semiconductor wafers at a high temperature (see, for example, Patent Document 1).

### PRIOR ART DOCUMENT

Patent Document 1: Japanese Patent Laid-open Publication No. 2014-103291

### SUMMARY

In one exemplary embodiment, a bonding method includes: preparing a first semiconductor substrate having a first surface and a second semiconductor substrate having a second surface; hydrophilizing the first surface of the first semiconductor substrate and the second surface of the second semiconductor substrate; bonding the first surface of the first semiconductor substrate and the second surface of the second semiconductor substrate after the hydrophilizing; and bonding the first surface of the first semiconductor substrate and the second surface of the second semiconductor substrate after the hydrophilizing. The enhancing of the bonding strength includes performing heat treatment on the first semiconductor substrate and the second semiconductor substrate in a first temperature range; and performing heat treatment on the first semiconductor substrate and the second semiconductor substrate at a target temperature after the performing of the heat treatment in the first temperature range. The first temperature range is lower than the target temperature.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

In the detailed description that follows, exemplary embodiments are described as illustrations only since various changes and modifications will become apparent to those skilled in the art from the following detailed description. The use of the same reference numerals in different figures indicates similar or identical items.

FIG. 1 is a plan view illustrating a bonding system according to a first exemplary embodiment;

FIG. 2 is a flowchart illustrating a bonding method according to the first exemplary embodiment;

FIG. 3 is a cross-sectional view illustrating an example of a first die carrier and a die;

FIG. 4 is a cross-sectional view illustrating an example of a second die carrier;

FIG. 5 is a cross-sectional view illustrating an example of the second die carrier and the die;

FIG. 6 is a cross-sectional view illustrating an example of a substrate;

FIG. 7 is a cross-sectional view illustrating an example of a die-attached substrate;

FIG. 8 is a cross-sectional view illustrating an example of an operation of a die arrangement device;

FIG. 9 is a cross-sectional view illustrating an example of electrostatic adsorption;

FIG. 10 is a cross-sectional view illustrating an example of an operation of a bonding device;

FIG. 11 is a cross-sectional view illustrating an example of an operation following the operation of FIG. 10;

FIG. 12 illustrates an example of a change over time in a control temperature during heat treatment;

FIG. 13 illustrates another example of a change over time in a control temperature during heat treatment;

FIG. 14 is a plan view illustrating a system according to a second exemplary embodiment;

FIG. 15 is a cross-sectional view illustrating an example of a combined wafer;

FIG. 16 is a flowchart illustrating a bonding method according to the second exemplary embodiment;

FIG. 17 is a cross-sectional view illustrating an example of a bonding device;

FIG. 18 is a cross-sectional view illustrating an example of an operation of the

bonding device;

FIG. 19 is a cross-sectional view illustrating an example of an operation following the operation of FIG. 18; and

FIG. 20 is a cross-sectional view illustrating an example of an operation following the operation of FIG. 19.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other exemplary embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, non-limitative exemplary embodiments of the present disclosure will be described in detail with reference to the accompanying drawings. Like reference numerals in the drawings denote like elements, and a duplicate description thereof will be omitted. In the present disclosure, the X-axis direction, the Y-axis direction and the Z-axis direction are orthogonal to each other. The X-axis direction and the Y-axis direction are horizontal directions, and the Z-axis direction is a vertical direction.

### First Exemplary Embodiment

### (Bonding System)

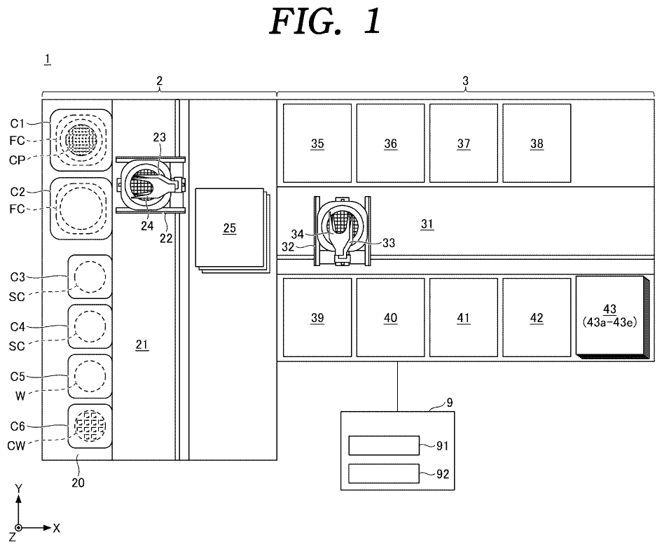

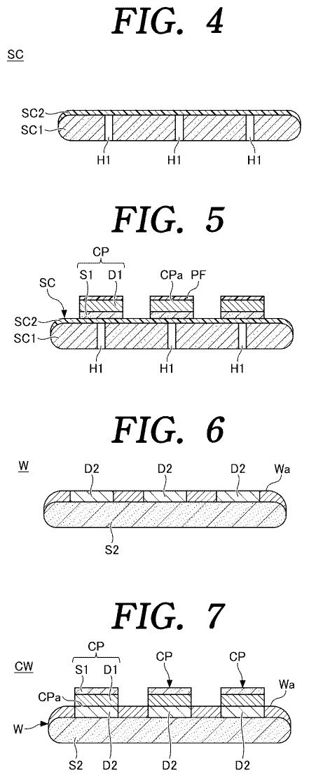

A bonding system 1 according to a first exemplary embodiment of the present disclosure will be described with reference to FIG. 1 to FIG. 11. As shown in FIG. 7, the bonding system 1 is configured to manufacture a die-attached substrate CW by bonding a die CP and a substrate W. The die CP is an example of a first semiconductor substrate, and the substrate W is an example of a second semiconductor substrate. The die-attached substrate CW includes the substrate W and a plurality of dies CP boned to the substrate W.

The die CP is equipped with a base substrate S1 and a device D1 formed on the base substrate S1. The base substrate S1 is, for example, a silicon wafer, a compound semiconductor wafer, or a glass substrate. The device D1 includes a semiconductor element, a circuit, or a terminal. The device D1 is formed on a bonding surface CPa of the die CP.

The substrate W is equipped with a base substrate S2 and a plurality of devices D2 formed on the base substrate S2. The base substrate S2 is, for example, a silicon wafer, a compound semiconductor wafer, or a glass substrate. The device D2 includes a semiconductor element, a circuit, or a terminal. The device D2 is formed on a bonding surface Wa of the substrate W.

The device D1 of the die CP is electrically connected to the device D2 of the substrate W. Although not illustrated in the drawings, a plurality of devices D1 may be electrically connected to one device D2. The plurality of devices D1 may have different functions, i.e., different electric circuits from each other. The device D1 of one die CP may be electrically connected to the device D2 of the substrate W via the device D1 of another die CP.

As shown in FIG. 1, the bonding system 1 is equipped with a carry-in/out station 2, a processing station 3, and a control device 9. The carry-in/out station 2 and the processing station 3 are arranged in this order from the negative X-axis direction toward the positive X-axis direction.

The carry-in/out station 2 is equipped with a placing table 20. Cassettes C1 to C6 are placed on the placing table 20. The cassette C1 accommodates therein a plurality of dies CP held by a first die carrier FC. The cassette C2 accommodates therein the first die carrier FC from which at least some of the dies CP have been detached and which has been completely used. The cassettes C3 and C4 accommodate therein a second die carrier SC. The cassette C5 accommodates therein the substrate W which has not yet been bonded to the die CP. The cassette C6 accommodates therein the die-attached substrate CW.

As shown in FIG. 3, the first die carrier FC includes a tape TP to which the die CP is attached, and a frame FR to which an outer edge of the tape TP is attached. A plurality of dies CP is arranged in an opening of the frame FR. The plurality of dies CP is obtained by, for example, dicing a substrate in a state the substrate is attached to the tape TP. The bonding surface CPa of the die CP is protected by a protective film PF before the dicing. The protective film PF is located opposite to the tape TP with respect to the die CP. The protective film PF is removed before the die CP is bonded to the substrate W.

As shown in FIG. 5, the second die carrier SC is configured to hold the plurality of dies CP detached from the first die carrier FC. The second die carrier SC is, for example, an electrostatic carrier. The electrostatic carrier electrostatically adsorbs the plurality of dies CP. The electrostatic carrier may electrostatically adsorb the plurality of dies CP and may also vacuum-adsorb the plurality of dies CP. Even after a loss of electrostatic attractive force, it is possible to keep holding the plurality of dies CP with vacuum attractive force.

The second die carrier SC holds the plurality of dies CP having the same function in the present exemplary embodiment, but may hold the plurality of dies CP having different functions from each other. In the latter case, a plurality of first die carriers FC is prepared for respective functions of the dies CP. The plurality of dies CP having different functions from each other can be transferred from the plurality of first die carriers FC to one second die carrier SC.

The die CP is transferred from the first die carrier FC to the second die carrier SC. This is to remove the protective film PF from the die CP and modify the bonding surface CPa of the die CP before the die CP is bonded to the substrate W. Also, this is to suppress damage to the tape TP of the first die carrier FC when the bonding surface CPa is modified. The second die carrier SC will be described in detail below.

As shown in FIG. 1, the carry-in/out station 2 is equipped with a transfer section 21, a first die carrier transfer arm 22, a second die carrier transfer arm 23, and a substrate transfer arm 24. Hereinafter, the first die carrier transfer arm 22, the second die carrier transfer arm 23, the substrate transfer arm 24 may be collectively described as transfer arms 22 to 24.

The transfer section 21 is adjacent to the placing table 20. The transfer arms 22 to 24 hold and transfer the first die carrier FC, the second die carrier SC, or the substrate W in the transfer section 21. Each of the transfer arms 22 to 24 is configured to be movable in horizontal directions (the X-axis direction and the Y-axis direction) and a vertical direction, and pivotable around a vertical axis.

A transfer device is composed of the transfer arms 22 to 24 and a non-illustrated driver configured to move or rotate the transfer arms 22 to 24. As shown in FIG. 1, the transfer arms 22 to 24 may be mounted on the same Y-axis slider and moved in the Y-axis direction at the same time. Alternatively, the transfer arms 22 to 24 may be mounted on different Y-axis sliders and moved in the Y-axis direction independently of each other. The transfer arms 22 to 24 are located at different heights from each other.

The carry-in/out station 2 is equipped with a transition device 25 located opposite to the placing table 20 with respect to the transfer section 21. The transition device 25 is provided between the transfer section 21 of the carry-in/out station 2 and a transfer section 31 of the processing station 3, and relays the first die carrier FC, the second die carrier SC, or the substrate W between the transfer section 21 and the transfer section 31. The transition device 25 may be stacked in the Z-axis direction.

The processing station 3 is equipped with the transfer section 31, a first die carrier transfer arm 32, a second die carrier transfer arm 33, and a substrate transfer arm 34. Hereinafter, the first die carrier transfer arm 32, the second die carrier transfer arm 33, the substrate transfer arm 34 may be collectively described as transfer arms 32 to 34.

The transfer section 31 extends in the X-axis direction. The transfer arms 32 to 34 hold and transfer the first die carrier FC, the second die carrier SC, or the substrate W in the transfer section 31. Each of the transfer arms 32 to 34 is configured to be movable in horizontal directions (the X-axis direction and the Y-axis direction) and a vertical direction, and pivotable around a vertical axis.

A transfer device is composed of the transfer arms 32 to 34 and a non-illustrated driver configured to move or rotate the transfer arms 32 to 34. As shown in FIG. 1, the transfer arms 32 to 34 may be mounted on the same X-axis slider and moved in the X-axis direction at the same time. Alternatively, the transfer arms 32 to 34 may be mounted on different X-axis sliders and moved in the X-axis direction independently of each other. The transfer arms 32 to 34 are located at different heights from each other.

The processing station 3 is equipped with a die arrangement device 35, a cleaning device 36, a first activation device 37, a first hydrophilizing device 38, an inverting device 39, a second activation device 40, a second hydrophilizing device 41, a bonding device 42, and an annealing device 43. These devices 35 to 43 are adjacent to the transfer section 31, and each of them is located in the positive Y-axis direction or the negative Y-axis direction of the transfer section 31.

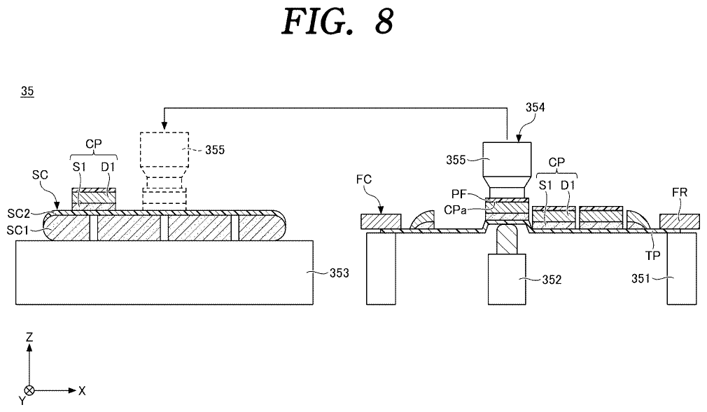

As shown in FIG. 8, the die arrangement device 35 is configured to transfer the die CP from the first die carrier FC to the second die carrier SC. Thus, it is possible to suppress the damage to the tape TP of the first die carrier FC when the bonding surface CPa is modified. The die arrangement device 35 will be described in detail below.

The cleaning device 36 is configured to remove the protective film PF from the die CP in a state where the die CP is held by the second die carrier SC. Also, the cleaning device 36 is configured to clean the bonding surface CPa of the die CP. Thus, the processing quality of the bonding surface CPa in subsequent processing can be improved.

The first activation device 37 is configured to activate the bonding surface CPa of the die CP in a state where the die CP is held by the second die carrier SC. The first activation device 37 is, for example, a plasma processing device. In the first activation device 37, an oxygen gas as a processing gas is excited into plasma under, for example, a decompressed atmosphere to be ionized. As oxygen ions are radiated to the bonding surface CPa of the die CP, the bonding surface CPa of the die CP is activated. The processing gas is not limited to the oxygen gas, and may be, for example, a nitrogen gas, or the like.

The first hydrophilizing device 38 is configured to hydrophilize the bonding surface CPa of the die CP in a state where the die CP is held by the second die carrier SC. For example, the first hydrophilizing device 38 supplies pure water (e.g., deionized water) onto the die CP while rotating the second die carrier SC held by a spin chuck. The pure water imparts OH groups (silanol groups) to the activated bonding surface CPa of the die CP. The die CP can be bonded to the substrate W by a hydrogen bond between the OH groups.

The inverting device 39 inverts the second die carrier SC in a state where the die CP is held by the second die carrier SC. The plurality of dies CP can be collectively inverted, and, thus, the bonding surface CPa of each die CP faces downwards. Also, the inverting device 39 may be provided inside the bonding device 42.

The second activation device 40 is configured to activate the bonding surface Wa of the substrate W. The second activation device 40 is, for example, a plasma processing device. In the second activation device 40, an oxygen gas as a processing gas is excited into plasma under, for example, a decompressed atmosphere to be ionized. As oxygen ions are radiated to the bonding surface Wa of the substrate W, the bonding surface Wa of the substrate W is activated. The processing gas is not limited to the oxygen gas, and may be, for example, a nitrogen gas, or the like.

The second hydrophilizing device 41 is configured to hydrophilize the bonding surface Wa of the substrate W. For example, the second hydrophilizing device 41 supplies pure water (e.g., deionized water) onto the substrate W while rotating the substrate W held by a spin chuck. The pure water imparts OH groups to the activated bonding surface Wa of the substrate W. The die CP can be bonded to the substrate W by a hydrogen bond between the OH groups.

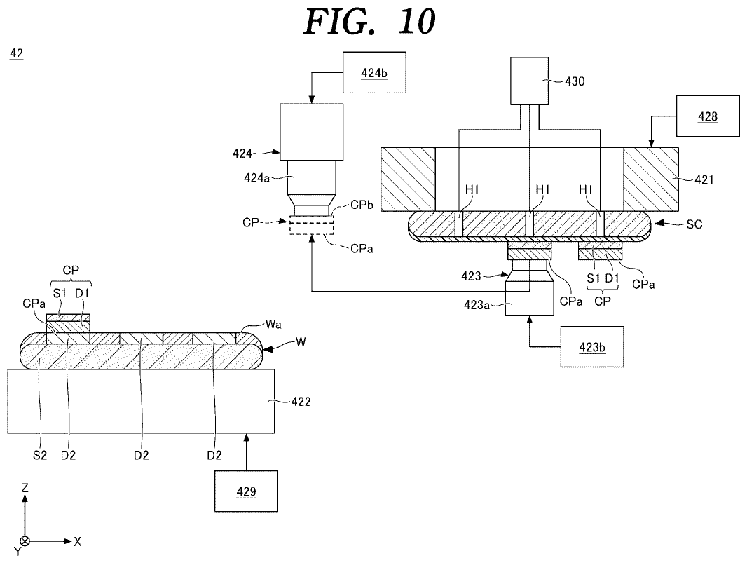

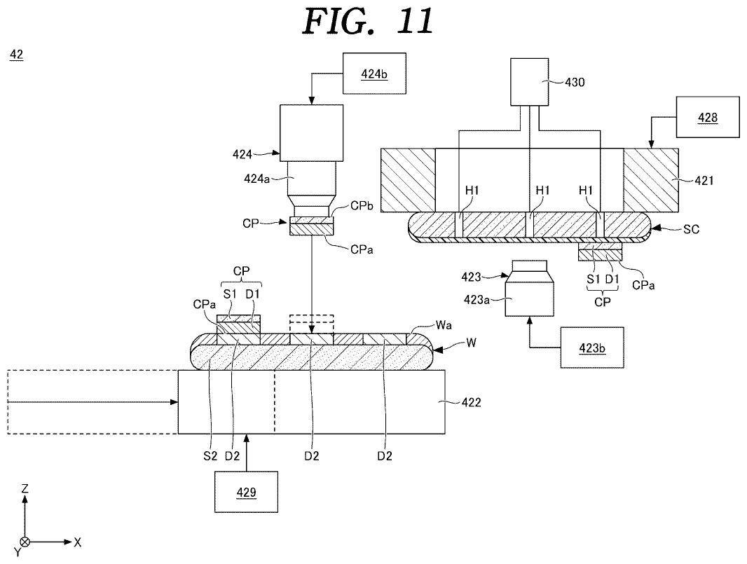

As shown in FIG. 10 and FIG. 11, the bonding device 42 is configured to detach the die CP from the second die carrier SC and make the bonding surface CPa of the detached die CP face the bonding surface Wa of the substrate W to bond the die CP to the substrate W. Thus, the die-attached substrate CW can be obtained. The device D1 of the die CP is electrically connected to the device D2 of the substrate W. The bonding device 42 will be described in detail below.

The annealing device 43 is configured to perform heat treatment on the die-attached substrate CW. Before the heat treatment, the die CP is bonded to the substrate W by the hydrogen bond between the OH groups. The heat treatment causes a dehydration condensation reaction, and a covalent bond is formed by the dehydration condensation reaction. Thus, bonding strength between the die CP and the substrate W can be enhanced. A plurality of annealing devices 43 is stacked, for example, in the Z-axis direction. The plurality of annealing devices 43 is configured to perform the heat treatment on the die-attached substrate CW at different set temperatures from each other. The plurality of annealing devices 43 includes an annealing device whose set temperature is equal to a target temperature, and an annealing device whose set temperature is in a first temperature range which is lower than the target temperature. The target temperature refers to a temperature at which the dehydration condensation reaction occurs and the covalent bond is formed. The target temperature is, for example, 350° C. or more. In the present exemplary embodiment, the plurality of annealing devices 43 includes five annealing devices 43a to 43e. The annealing devices 43a, 43b, 43c, 43d and 43e have set temperatures of 50° C., 100° C., 150° C., 200° C. and 350° C. (target temperature), respectively. The number of the annealing devices 43 is not limited to the example shown in the drawings.

The control device 9 is, for example, a computer, and includes a calculator 91, such as a central processing unit (CPU), and a storage 92, such as a memory. The storage 92 stores thereon a program for controlling various processing performed in the bonding system 1. The control device 9 causes the calculator 91 to execute the program stored on the storage 92 to control an operation of the bonding system 1. The bonding system 1 is equipped with a unit controller configured to control an operation of each unit of the bonding system 1, and may be equipped with a system controller configured to collectively control a plurality of unit controllers. The control device 9 may be composed of the unit controllers and the system controller.

### (Bonding Method)

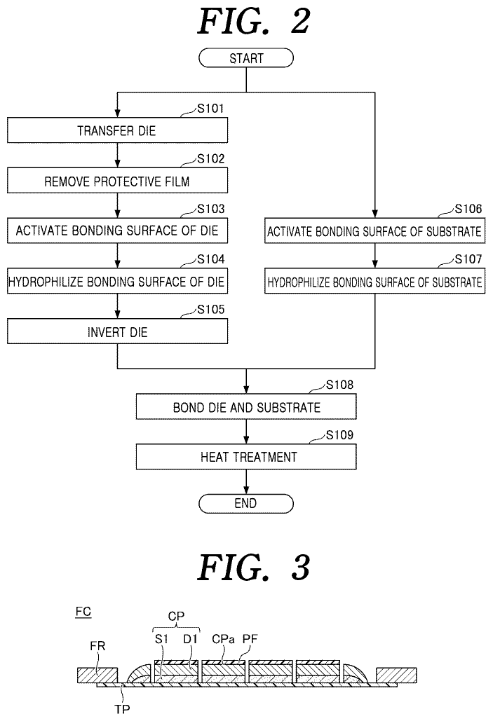

Referring to FIG. 2, a bonding method according to the first exemplary embodiment will be described. The processing shown in FIG. 2 is performed under the control of the control device 9.

First, the first die carrier transfer arm 22 takes out the plurality of dies CP together with the first die carrier FC from the cassette C1, and transfers them to the transition device 25. Then, the first die carrier transfer arm 32 takes out the plurality of dies CP together with the first die carrier FC from the transition device 25, and transfers them to the die arrangement device 35.

Also, the second die carrier transfer arm 23 takes out the second die carrier SC from the cassette C3, and transfers it to the transition device 25. Then, the second die carrier transfer arm 33 takes out the second die carrier SC from the transition device 25, and transfers it to the die arrangement device 35.

Thereafter, the die arrangement device 35 transfers the die CP from the first die carrier FC to the second die carrier SC (process S101). Then, the second die carrier transfer arm 33 takes out the plurality of dies CP together with the second die carrier SC from the die arrangement device 35, and transfers them to the cleaning device 36.

Thereafter, the cleaning device 36 removes the protective film PF from the die CP in a state where the die CP is held by the second die carrier SC (process S102). Then, the second die carrier transfer arm 33 takes out the plurality of dies CP together with the second die carrier SC from the cleaning device 36, and transfers them to the first activation device 37.

Thereafter, the first activation device 37 activates the bonding surface CPa of the die CP in a state where the die CP is held by the second die carrier SC (process S103). Then, the second die carrier transfer arm 33 takes out the plurality of dies CP together with the second die carrier SC from the first activation device 37, and transfers them to the first hydrophilizing device 38.

Thereafter, the first hydrophilizing device 38 hydrophilizes the bonding surface CPa of the die CP in a state where the die CP is held by the second die carrier SC (process S104). Then, the second die carrier transfer arm 33 takes out the plurality of dies CP together with the second die carrier SC from the first hydrophilizing device 38, and transfers them to the inverting device 39.

Thereafter, the inverting device 39 inverts the second die carrier SC in a state where the die CP is held by the second die carrier SC (process S105). Then, the second die carrier transfer arm 33 takes out the plurality of dies CP together with the second die carrier SC from the inverting device 39, and transfers them to the bonding device 42.

The above-described processes S101 to S105 are performed in parallel with the following processes S106 to S107. First, the substrate transfer arm 24 takes out the substrate W from the cassette C5, and transfers it to the transition device 25. Then, the substrate transfer arm 34 takes out the substrate W from the transition device 25, and transfers it to the second activation device 40.

Thereafter, the second activation device 40 activates the bonding surface Wa of the substrate W (process S106). Then, the substrate transfer arm 34 takes out the substrate W from the second activation device 40, and transfers it to the second hydrophilizing device 41.

Thereafter, the second hydrophilizing device 41 hydrophilizes the bonding surface Wa of the substrate W (process S107). Then, the substrate transfer arm 34 takes out the substrate W from the second hydrophilizing device 41, and transfers it to the bonding device 42.

Thereafter, the bonding device 42 detaches the die CP from the second die carrier SC and makes the bonding surface CPa of the detached die CP face the bonding surface Wa of the substrate W to bond the die CP to the substrate W (process S108). Thus, the die-attached substrate CW can be obtained. Then, the substrate transfer arm 34 takes out the die-attached substrate CW from the bonding device 42, and transfers it to the annealing device 43.

Thereafter, the annealing device 43 performs the heat treatment on the die-attached substrate CW (process S109). Thus, the bonding strength between the die CP and the substrate W can be enhanced. The heat treatment will be described in detail below. Then, the substrate transfer arm 34 takes out the die-attached substrate CW from the annealing device 43, and transfers it to the transition device 25. Finally, the substrate transfer arm 24 takes out the die-attached substrate CW from the transition device 25, and accommodates it in the cassette C6. The die-attached substrate CW being accommodated in the cassette C6 is carried out of the bonding system 1.

After the process S101, the first die carrier transfer arm 32 takes out the first die carrier FC from the die arrangement device 35, and transfers it to the transition device 25. Then, the first die carrier transfer arm 22 takes out the first die carrier FC from the transition device 25, and accommodates it in the cassette C2.

After the process S108, the second die carrier transfer arm 33 takes out the second die carrier SC from the bonding device 42, and transfers it to the transition device 25. Then, the second die carrier transfer arm 23 takes out the second die carrier SC from the transition device 25, and accommodates it in the cassette C4.

### (Die Arrangement Device)

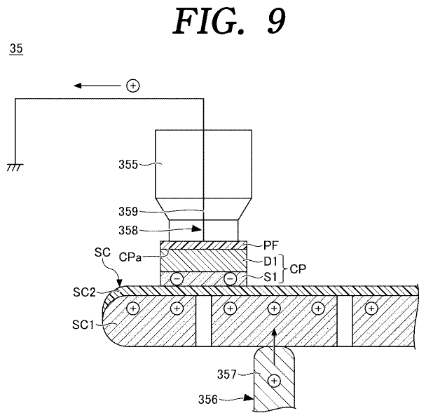

Referring to FIG. 8 and FIG. 9, the die arrangement device 35 and the second die carrier SC will be described in detail. As shown in FIG. 8, the die arrangement device 35 transfers the die CP from the first die carrier FC to the second die carrier SC. Thus, when the bonding surface CPa is modified, the die carrier having a relatively high durability can be used.

The second die carrier SC is not particularly limited as long as it has a higher durability than the first die carrier FC, but may be, for example, an electrostatic carrier. The electrostatic carrier is equipped with, for example, a conductive substrate SC1 and an insulating film SC2, and electrostatically adsorbs the die CP located opposite to the conductive substrate SC1 with respect to the insulating film SC2.

The conductive substrate SC1 is formed of, for example, silicon, aluminum, an aluminum alloy, stainless steel, or titanium. The conductive substrate SC1 may include one or more through holes H1 for each die CP. The die CP can be separated from the second die carrier SC by supplying a gas into the through holes H1 or inserting non-illustrated pins into the through holes H1. The number and arrangement of the through holes H1 are not particularly limited.

As shown in FIG. 9, the insulating film SC2 maintains the electrostatic attractive force by restricting movement of charges between the base substrate S1 of the die CP and the conductive substrate SC1. The insulating film SC2 may have a dielectric breakdown voltage of preferably 30 kV or more, and more preferably 40 kV or more.

The insulating film SC2 may be formed of a flexible material, specifically a material having an elastic modulus of 2 GPa or less, and more preferably 0.5 GPa or less. In view of the durability when the bonding surface CPa is modified, for example, polyimide or ethylene vinyl acetate (EVA) is used. The insulating film SC2 has a thickness of, for example, 10 μm.

The insulating film SC2 may include through holes communicating with the through holes H1 of the conductive substrate SC1. Preferably, the through hole of the insulating film SC2 may have a smaller diameter than the through hole H1 of the conductive substrate SC1. Alternatively, the insulating film SC2 may not include through holes. In this case, the die CP can be separated by inflating the insulating film SC2.

Preferably, the second die carrier SC may have the same diameter as the substrate W. In this case, items with the same model number (i.e., the same size and the same shape) can be used in the second die carrier transfer arm 23 and the substrate transfer arm 24, which results in a reduction in cost. Also, items with the same model number can be used in the second die carrier transfer arm 33 and the substrate transfer arm 34, the first activation device 37 and the second activation device 40, or the first hydrophilizing device 38 and the second hydrophilizing device 41, which results in a reduction in cost. Further, it is possible to suppress an increase in size of the device.

As shown in FIG. 8, the die arrangement device 35 is equipped with a first die carrier holder 351, a pressing device 352, a second die carrier holder 353, and a die transfer mechanism 354. The first die carrier holder 351 is configured to hold the first die carrier FC from below the first die carrier FC. The first die carrier FC holds the die CP with the bonding surface CPa of the die CP facing upwards. The first die carrier holder 351 holds the frame FR of the first die carrier FC, but does not hold the tape TP.

The pressing device 352 is configured to locally press the die CP via the tape TP and locally deform the tape TP. Since the pressing device 352 can push up the dies CP individually, it is possible to suppress interference between the dies CP when the die CP is picked up. It is possible to move the pressing device 352 and the first die carrier holder 351 relatively, and also possible to change a position where the die CP is pushed upwards.

The second die carrier holder 353 is configured to hold the second die carrier SC from below the second die carrier SC. The second die carrier SC holds the die CP with the bonding surface CPa of the die CP facing upwards. Likewise, the first die carrier FC holds the die CP with the bonding surface CPa of the die CP facing upwards. Thus, the die transfer mechanism 354 is configured to transfer the die CP with the bonding surface CPa of the die CP facing upwards. The die transfer mechanism 354 does not invert the die CP.

The die transfer mechanism 354 is equipped with an adsorption head 355 configured to adsorb the die CP. The adsorption head 355 is disposed above the die CP. The bonding surface CPa of the die CP is covered by the protective film PF, and the adsorption head 355 adsorbs the die CP via the protective film PF. The adsorption head 355 is in contact with the protective film PF, but is not in contact with the die CP. Therefore, it is possible to suppress damage to the die CP.

As shown in FIG. 9, the die arrangement device 35 is equipped with a charge supply 356 and a charge remover 358. The charge supply 356 is configured to apply a voltage to the conductive substrate SC1 and thus supplies a charge of a first polarity (e.g., a positive charge) to the conductive substrate SC1. The charge remover 358 is configured to apply eliminate the charge of the first polarity from the die CP and thus leaves a charge of a second polarity to the first polarity (e.g., a negative charge) in the die CP.

The charge of the first polarity is accumulated in the conductive substrate SC1, whereas the charge of the second polarity is accumulated in the die CP. As a result, a potential difference is generated between the conductive substrate SC1 and the die CP with the insulating film SC2 interposed therebetween, and, thus, the electrostatic attractive force is generated. The generated electrostatic attractive force is maintained even after the applying of the voltage to the conductive substrate SC1 and the charge removing of the die CP are released.

The charge supply 356 is equipped with a feed pin 357 in contact with, for example, the conductive substrate SC1. The feed pin 357 is provided in, for example, the second die carrier holder 353 and electrically connected to a non-illustrated power supply. The charge remover 358 is equipped with, for example, an earth wire 359. The earth wire 359 eliminates the charge of the first polarity from the die CP via, for example, the protective film PF.

In the present exemplary embodiment, the earth wire 359 is embedded in the adsorption head 355. However, the earth wire 359 may be provided separately from the adsorption head 355. In the present exemplary embodiment, one die CP is electrostatically adsorbed at a time. However, a plurality of dies CP may be arranged on the insulating film SC2, and then, electrostatically adsorbed at the same time.

As described above, the insulating film SC2 is formed of the flexible material. When the die CP is pressed by the insulating film SC2 with the electrostatic attractive force, the insulating film SC2 is deformed to allow air to be escaped from a space between the die CP and the insulating film SC2, and, thus, the vacuum attractive force is generated between the die CP and the insulating film SC2.

Even when the charge leaks from the conductive substrate SC1 or the die CP and the electrostatic attractive force is lost, it is possible to keep holding the plurality of dies CP with the vacuum attractive force. The charge may leak due to, for example, the supply of the processing liquid to the die CP when the protective film PF is removed or the bonding surface CPa is modified.

### (Bonding Device)

Referring to FIG. 10 and FIG. 11, the bonding device 42 will be described in detail. As shown in FIG. 10 and FIG. 11, the bonding device 42 detaches the die CP from the second die carrier SC and makes the bonding surface CPa of the detached die CP face the bonding surface Wa of the substrate W to bond the die CP to the substrate W. Thus, the die-attached substrate CW can be obtained. The device D1 of the die CP is electrically connected to the device D2 of the substrate W.

The bonding device 42 is equipped with, for example, a die carrier holder 421, a substrate holder 422, a first die transfer mechanism 423, and a second die transfer mechanism 424. The die carrier holder 421 is configured to hold the second die carrier SC from above the second die carrier SC in a state where the bonding surface CPa of each of the plurality of dies CP held by the second die carrier SC faces downwards. The substrate holder 422 is configured to hold the substrate W from below the substrate W in a state where the bonding surface Wa of the substrate W faces upwards. The first die transfer mechanism 423 is configured to receive the die CP from the second die carrier SC and transfers the die CP with the bonding surface CPa of the die CP facing downwards. The second die transfer mechanism 424 is configured to receive the die CP from the first die transfer mechanism 423 and bonds the die CP to the substrate W in a state where the bonding surface CPa of the die CP faces downwards.

According to the present exemplary embodiment, the inverting device 39 inverts the second die carrier SC before the die carrier holder 421 holds the second die carrier SC. Since the plurality of dies CP can be collectively inverted in advance, the bonding surface CPa of each die CP may face downwards. While the first die transfer mechanism 423 and the second die transfer mechanism 424 transfer each die CP individually, each die CP is not inverted individually. Since a mechanism configured to invert the die CP individually can be omitted, it is possible to suppress dust generation from the mechanism. Also, the first die transfer mechanism 423 and the second die transfer mechanism 424 can be simplified in structure. Further, the number of inversions can be reduced, and the throughput can be improved.

According to the present exemplary embodiment, the die carrier holder 421 holds the second die carrier SC from above the second die carrier SC, and the substrate holder 422 holds the substrate W from below the substrate W. Since the substrate holder 422 holds the substrate W which is greater in diameter than the die CP and heavier than the die CP from below the substrate W, the substrate W can be stably held. Therefore, the die CP can be bonded to a desired position on the substrate W. The positional accuracy in bonding is determined mainly by the accuracy in position alignment of the second die transfer mechanism 424 and the substrate holder 422. The accuracy in position alignment of the first die transfer mechanism 423 and the die carrier holder 421 may be lower than the accuracy in position alignment of the second die transfer mechanism 424 and the substrate holder 422. For this reason, even when the die carrier holder 421 holds the second die carrier SC from above the second die carrier SC, the positional accuracy in bonding is not degraded.

Although the die carrier holder 421 holds the second die carrier SC in the present exemplary embodiment, the die carrier holder 421 may hold the first die carrier FC. If the bonding system 1 does not modify the bonding surface CPa of the die CP, the die CP does not need to be transferred from the first die carrier FC to the second die carrier SC. Therefore, the die carrier holder 421 may hold the first die carrier FC.

When the die carrier holder 421 holds the first die carrier FC, the inverting device 39 just needs to invert the first die carrier FC. Since the plurality of dies CP can be collectively inverted in advance, the bonding surface CPa of each die CP may face downwards. Since a mechanism configured to invert the die CP individually can be omitted, it is possible to suppress dust generation from the mechanism. Also, the first die transfer mechanism 423 and the second die transfer mechanism 424 can be simplified in structure. Further, the number of inversions can be reduced, and the throughput can be improved. Furthermore, the positional accuracy in bonding between the die CP and the substrate W can be improved.

The first die transfer mechanism 423 is equipped with, for example, a first adsorption head 423a and a first driver 423b. The first adsorption head 423a is located under the die CP to adsorb the bonding surface CPa of the die CP. The first adsorption head 423a is configured to be movable in, for example, the X-axis direction and the Z-axis direction. The first driver 423b is configured to move the first adsorption head 423a.

Preferably, the first adsorption head 423a may adsorb the bonding surface CPa of the die CP in a non-contact manner. That is, it is desirable for the first adsorption head 423a to adsorb the bonding surface CPa of the die CP in a state where a gap with respect to the die CP is formed. It is possible to suppress contamination of the bonding surface CPa of the die CP. The first adsorption head 423a is of, for example, an ultrasonic type or a Bernoulli type. The ultrasonic type adsorption head uses a squeeze effect by ultrasonic vibration, and the Bernoulli type adsorption head uses a Bernoulli effect. The ultrasonic type adsorption head can suppress occurrence of an error in the horizontal direction as compared to the Bernoulli type adsorption head.

The second die transfer mechanism 424 is equipped with, for example, a second adsorption head 424a and a second driver 424b. The second adsorption head 424a is located above the die CP to adsorb a rear surface CPb of the die CP opposite to the bonding surface CPa of the die CP. It is not a problem to contaminate the rear surface CPb, and, thus, the second adsorption head 424a is in contact with the die CP.

The second adsorption head 424a is configured to be movable in, for example, the X-axis direction, the Y-axis direction, the Z-axis direction, and the 0 direction. The 0 direction 0 refers to the direction of rotation around a vertical axis as the central axis of rotation. That is, the second adsorption head 424a may rotate around the vertical axis as the central axis of rotation. The second driver 424b is configured to move the second adsorption head 424a.

As shown in FIG. 10 and FIG. 11, the bonding device 42 may be equipped with a first moving mechanism 428 and a second moving mechanism 429. The first moving mechanism 428 is configured to move the die carrier holder 421 in the horizontal direction. The first moving mechanism 428 may move the die carrier holder 421 in the vertical direction. The second moving mechanism 429 is configured to move the substrate holder 422 in the horizontal direction. The second moving mechanism 429 may move the substrate holder 422 in the vertical direction.

According to the present exemplary embodiment, the die carrier holder 421 holds the second die carrier SC from above the second die carrier SC, and the substrate holder 422 holds the substrate W from below the substrate W. For this reason, the second die carrier SC and the substrate W can be located at different heights from each other. Therefore, the die carrier holder 421 and the substrate holder 422 can be located at different heights from each other. As a result, when the die carrier holder 421 is viewed from the top, a movement range of the die carrier holder 421 can overlap a movement range of the substrate holder 422. Thus, a footprint of the bonding device 42 can be reduced.

The substrate holder 422 is configured to be movable in a first axis direction which is horizontal and a second axis direction which is orthogonal to the first axis direction. The first axis direction is, for example, the X-axis direction, and the second axis direction is, for example, Y-axis direction. The substrate holder 422 is configured to be movable in both the positive X-axis direction and the negative X-axis direction. Also, the substrate holder 422 is configured to be movable in both the positive Y-axis direction and the negative Y-axis direction.

The die carrier holder 421 may be moved in both the first axis direction and the second axis direction, or may be moved in only the second axis direction between the first axis direction and the second axis direction. In the latter case, when the die carrier holder 421 is viewed from the top, the movement range of the die carrier holder 421 and the movement range of the substrate holder 422 may overlap the first axis direction. In the latter case, the footprint of the bonding device 42 can be further reduced in the former case.

As shown in FIG. 10 and FIG. 11, the bonding device 42 may be equipped with a pressing mechanism 430. The pressing mechanism 430 is configured to press the die CP downwards with respect to the second die carrier SC held by the die carrier holder 421. The pressing mechanism 430 presses the die CP individually downwards to separate the die CP individually from the second die carrier SC.

The pressing mechanism 430 separates the die CP from the second die carrier SC by, for example, supplying a gas into the through holes H1 of the conductive substrate SC1 or inserting non-illustrated pins into the through holes H1. The number and arrangement of the through holes H1 are not particularly limited. The insulating film SC2 may include or may not include through holes.

Although the die carrier holder 421 holds the second die carrier SC in the present exemplary embodiment, the die carrier holder 421 may hold the first die carrier FC as described above.

### (Heat Treatment)

The present inventors have found that when the die-attached substrate CW is heat-treated at a predetermined target temperature, the bonding strength between the die CP and the substrate W may decrease. Also, the present inventors have found that when the die-attached substrate CW is heat-treated in a first temperature range, which is lower than the target temperature, before being heat-treated at the target temperature, it is possible to suppress the decrease in bonding strength of the die-attached substrate CW. The present inventors surmise that the reason for this effect is as follows.

Before the heat treatment, the die CP is bonded to the substrate W by the hydrogen bond between the OH groups. The heat treatment causes a dehydration condensation reaction represented by the following reaction formula (1) and an oxidation reaction represented by the following reaction formula (2). Thus, the bonding strength between the die CP and the substrate W is enhanced.

Si—OH +Si—OH→Si—O—Si+H2O (1)

Si+H2O→SiO+H2 (2)

Herein, when H2O produced by the dehydration condensation reaction represented by the reaction formula (1) remains on a bonding interface between the die CP and the substrate W, voids are formed in the bonding surface, which causes the decrease in bonding strength between the die CP and the substrate W. For example, when the amount of H2O produced (hereinafter, also referred to as “H2O generation amount”) by the dehydration condensation reaction represented by the reaction formula (1) is greater than the amount of H2O consumed (absorbed) (hereinafter, also referred to as “H2O absorption amount”) by the oxidation reaction represented by the reaction formula (2), H2O is likely to remain on the bonding interface between the die CP and the substrate W. For this reason, it is important to control a balance between the H2O generation amount by the dehydration condensation reaction and the H2O absorption amount by the oxidation reaction during the heat treatment.

Hereinafter, the heat treatment (process S109) of the bonding method according to the first exemplary embodiment will be described in detail.

In the process S109, the die-attached substrate CW is heat-treated in the first temperature range, which is lower than the predetermined target temperature, before being heat-treated at the target temperature. A reaction rate of the dehydration condensation reaction decreases as the temperature decreases. Since the die-attached substrate CW is heat-treated in the first temperature range, which is lower than the target temperature, before being heat-treated at the target temperature, a temperature rising rate of the die-attached substrate CW becomes gentle. Therefore, it is possible to suppress the H2O generation amount by the dehydration condensation reaction from exceeding the H2O absorption amount by the oxidation reaction. As a result, it is possible to suppress H2O from remaining on the bonding surface between the die CP and the substrate W and thus possible to suppress the decrease in bonding strength between the die CP and the substrate W.

The target temperature refers to a temperature at which the dehydration condensation reaction occurs and the covalent bond is formed. The target temperature is, for example, 350° C. or more.

The heat treatment in the first temperature range may include maintaining an atmosphere in which the die-attached substrate CW is provided in a temperature range of 100° C. to less than 150° C. In the temperature range of 100° C. to less than 150° C., the dehydration reaction is caused by evaporation of water. For this reason, the atmosphere in which the die-attached substrate CW is provided is maintained in the temperature range of 100° C. to less than 150° to cause the dehydration reaction by the evaporation of water. Thus, H2O may be produced before the atmosphere in which the die-attached substrate CW is provided reaches the target temperature. As a result, it is possible to suppress a sharp increase in the H2O generation amount when the die-attached substrate CW is heat-treated at the target temperature, and, thus, it is possible to suppress the H2O generation amount from exceeding the H2O absorption amount. The atmosphere in which the die-attached substrate CW is provided may be maintained in the temperature range of 100° C. to less than 150° for a longer period of time, e.g., 5 minutes, for which the temperature of the die-attached substrate CW reaches the temperature range of 100° C. to less than 150°.

The heat treatment in the first temperature range may include maintaining the atmosphere in which the die-attached substrate CW is provided in a temperature range of 300° C. to less than 350° C. In the temperature range of 300° C. to less than 350° C., the dehydration reaction is caused by removal of adsorption water. For this reason, the atmosphere in which the die-attached substrate CW is provided is maintained in the temperature range of 300° C. to less than 350° to cause the dehydration reaction by the removal of adsorption water. Thus, H2O may be produced before the atmosphere in which the die-attached substrate CW is provided reaches the target temperature. As a result, it is possible to suppress the sharp increase in the H2O generation amount when the die-attached substrate CW is heat-treated at the target temperature, and, thus, it is possible to suppress the H2O generation amount from exceeding the H2O absorption amount. The atmosphere in which the die-attached substrate CW is provided may be maintained in the temperature range of 300° C. to less than 350° for a longer period of time, e.g., 5 minutes, for which the temperature of the die-attached substrate CW reaches the temperature range of 300° C. to less than 350°.

Hereinafter, an example method of performing the heat treatment on the die-attached substrate CW in the annealing device 43 will be described. The annealing device 43 includes the five annealing devices 43a to 43e.

First, the substrate transfer arm 34 takes out the die-attached substrate CW from the bonding device 42, and transfers it to the annealing device 43a.

Thereafter, the annealing device 43a performs heat treatment on the die-attached substrate CW. A set temperature of the annealing device 43a is 50° C. For this reason, the die-attached substrate CW is heat-treated in an atmosphere of 50° C. The annealing device 43a performs the heat treatment on the die-attached substrate CW for, e.g., 5 minutes. Then, the substrate transfer arm 34 takes out the die-attached substrate CW from the annealing device 43a, and transfers it to the annealing device 43b.

Thereafter, the annealing device 43b performs heat treatment on the die-attached substrate CW. A set temperature of the annealing device 43b is 100° C. For this reason, the die-attached substrate CW is heat-treated in an atmosphere of 100° C. The annealing device 43b performs the heat treatment on the die-attached substrate CW for, e.g., 5 minutes. Then, the substrate transfer arm 34 takes out the die-attached substrate CW from the annealing device 43b, and transfers it to the annealing device 43c.

Thereafter, the annealing device 43c performs heat treatment on the die-attached substrate CW. A set temperature of the annealing device 43c is 150° C. For this reason, the die-attached substrate CW is heat-treated in an atmosphere of 150° C. The annealing device 43c performs the heat treatment on the die-attached substrate CW for, e.g., 5 minutes. Then, the substrate transfer arm 34 takes out the die-attached substrate CW from the annealing device 43c, and transfers it to the annealing device 43d.

Thereafter, the annealing device 43d performs heat treatment on the die-attached substrate CW. A set temperature of the annealing device 43d is 200° C. For this reason, the die-attached substrate CW is heat-treated in an atmosphere of 200° C. The annealing device 43d performs the heat treatment on the die-attached substrate CW for, e.g., 5 minutes. Then, the substrate transfer arm 34 takes out the die-attached substrate CW from the annealing device 43d, and transfers it to the annealing device 43e.

Thereafter, the annealing device 43e performs heat treatment on the die-attached substrate CW. A set temperature of the annealing device 43e is 350° C. (target temperature). For this reason, the die-attached substrate CW is heat-treated in an atmosphere of 350° C. Thus, the bonding strength between the die CP and the substrate W is enhanced. The annealing device 43e performs the heat treatment on the die-attached substrate CW for, e.g., 60 minutes. Then, the substrate transfer arm 34 takes out the die-attached substrate CW from the annealing device 43e, and transfers it to the transition device 25. Finally, the substrate transfer arm 24 takes out the die-attached substrate CW from the transition device 25, and accommodates it in the cassette C6. The die-attached substrate CW being accommodated in the cassette C6 is carried out of the bonding system 1.

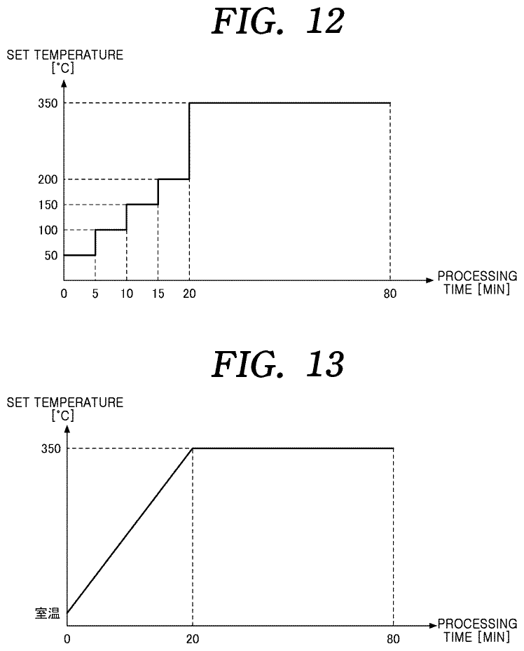

As described above, according to the first exemplary embodiment, the die-attached substrate CW is transferred to the five annealing devices 43a to 43e in this order. Thus, as shown in FIG. 12, the temperature of the atmosphere in which the die-attached substrate CW is provided can be increased in a stepwise manner. In this case, during the heat treatment in the process S109, the temperature rising rate of the die-attached substrate CW becomes gentle. Therefore, it is possible to suppress the H2O generation amount by the dehydration condensation reaction from exceeding the H2O absorption amount by the oxidation reaction. As a result, it is possible to suppress H2O from remaining on the bonding surface between the die CP and the substrate W and thus possible to suppress the decrease in bonding strength between the die CP and the substrate W. Also, during the heat treatment, the set temperatures of the respective annealing devices 43a to 43e are not changed. For this reason, time required for increasing the temperatures of the respective annealing devices 43a to 43e is not necessary. Further, it is possible to reduce the power consumption of the annealing devices 43a to 43e.

The H2O generation amount during the heat treatment varies depending on the number of dies CP, the size of the die CP, the thickness of the die CP, and the arrangement pitch of the dies CP. Therefore, it is desirable to determine temperature rising conditions during the heat treatment depending on the number of dies CP, the size of the die CP, the thickness of the die CP, and the arrangement pitch of the dies CP. In this case, it is possible to suppress H2O from remaining on the bonding surface between the die CP and the substrate W and also possible to reduce the time required for the heat treatment. The temperature rising conditions include, for example, time required for performing the heat treatment on the die-attached substrate CW in each of the annealing devices 43a to 43e. The temperature rising conditions may include the set temperatures of the respective annealing devices 43a to 43e.

Also, in the first exemplary embodiment, it has been described that the die-attached substrate CW is transferred to the five annealing devices 43a to 43e in this order. However, the present disclosure is not limited thereto. For example, the set temperature of one annealing device 43 may be changed to increase the temperature of the atmosphere in which the die-attached substrate CW is provided in a stepwise manner.

Further, in the first exemplary embodiment, it has been described that the temperature of the atmosphere in which the die-attached substrate CW is provided is increased in the stepwise manner. However, the present disclosure is not limited thereto. For example, as shown in FIG. 13, the temperature of the atmosphere in which the die-attached substrate CW is provided may be continuously increased from the room temperature to the target temperature. In this case, it is desirable to increase the set temperature from the room temperature to 350° C. (target temperature) at a temperature rising rate of 10° C./min or less. Thus, it is possible to suppress the H2O generation amount from exceeding the H2O absorption amount regardless of the type of the film to be bonded. Therefore, it becomes easy to suppress H2O from remaining on the bonding surface between the die CP and the substrate W.

Furthermore, in the first exemplary embodiment, it has been described that the bonding system 1 is equipped with the annealing device 43. However, the present disclosure is not limited thereto. For example, the annealing device 43 may be provided separately from the bonding system 1.

### Second Exemplary Embodiment

### (System)

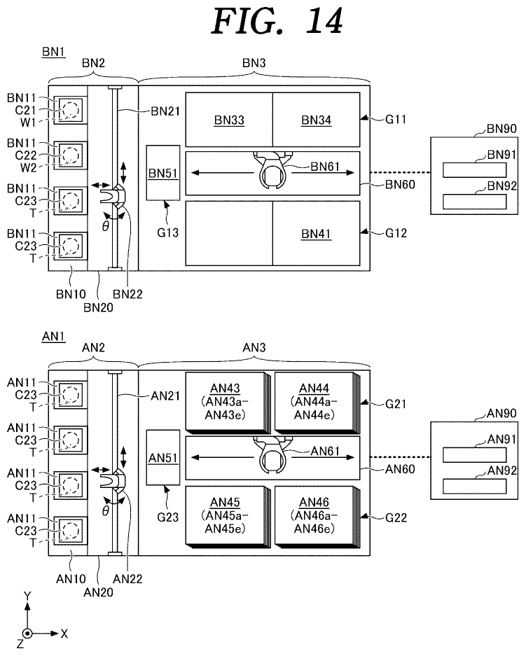

A system according to a second exemplary embodiment of the present disclosure will be described with reference to FIG. 14 to FIG. 20. The system is equipped with a bonding system BN1 and an annealing system AN1.

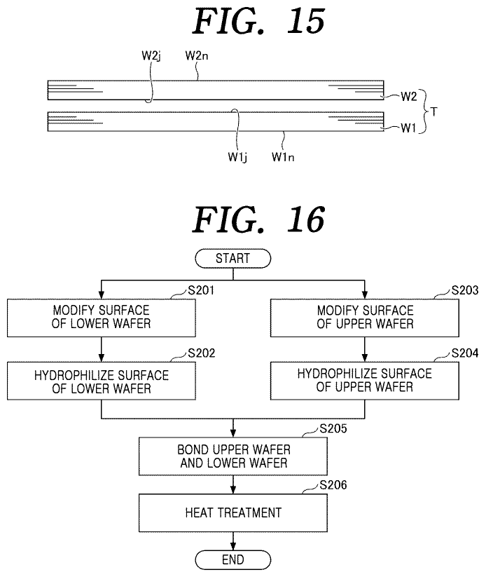

The bonding system BN1 is configured to manufacture a combined substrate by bonding the first semiconductor substrate and the second semiconductor substrate. As shown in FIG. 15, a substrate disposed on the lower side when the bonding is performed is referred to as a lower wafer W1, and a substrate disposed on the upper side when the bonding is performed is referred to as an upper wafer W2. Herein, the lower wafer W1 corresponds to the first semiconductor substrate, and the upper wafer W2 corresponds to the second semiconductor substrate. However, the combination may be reversed, so the lower wafer W1 may correspond to the second semiconductor substrate, and the upper wafer W2 may correspond to the first semiconductor substrate.

A combined wafer T is obtained by bonding the lower wafer W1 and the upper wafer W2. Among plate surfaces of the lower wafer W1, the plate surface to be bonded to the upper wafer W2 will be referred to as “bonding surface W1ⱼ”, and the plate surface opposite to the bonding surface W1ⱼ will be referred to as “non-bonding surface W1ₙ”. Further, among plate surfaces of the upper wafer W2, the plate surface to be bonded to the lower wafer W1 will be referred to as “bonding surface W2ⱼ”, and the plate surface opposite to the bonding surface W2ⱼ will be referred to as “non-bonding surface W2n”.

The lower wafer W1 has a semiconductor substrate, such as a silicon wafer, and a film formed on the semiconductor substrate. Instead of the semiconductor substrate, a glass substrate may be used. The film includes, for example, a device layer and a bonding layer. The device layer includes a plurality of electronic circuits. The bonding layer is formed on the device layer. The bonding layer is, for example, a silicon oxide film, a silicon nitride film, or a silicon carbonitride film.

The upper wafer W2 has a semiconductor substrate, such as a silicon wafer, and a film formed on the semiconductor substrate. Instead of the semiconductor substrate, a glass substrate may be used. The film includes, for example, a device layer and a bonding layer. The device layer includes a plurality of electronic circuits. The bonding layer is formed on the device layer. The bonding layer is, for example, a silicon oxide film, a silicon nitride film, or a silicon carbonitride film.

Further, either one of the lower wafer W1 and the upper wafer W2 may not include the device layer.

As shown in FIG. 14, the bonding system BN1 includes a carry-in/out station BN2 and a processing station BN3. The carry-in/out station BN2 and the processing station BN3 are arranged in this order along the positive X-axis direction. The carry-in/out station BN2 and the processing station BN3 are connected as one body.

The carry-in/out station BN2 is equipped with a placing table BN10 and a transfer section BN20. The placing table BN10 includes a plurality of placing plates BN11. Cassettes C21, C22 and C23 each of which accommodates therein a plurality of (e.g., 25) substrates horizontally are placed on the placing plates BN11, respectively. The cassette C21 accommodates therein the lower wafer W1, the cassette C22 accommodates therein the upper wafer W2, and the cassette C23 accommodates therein the combined wafer T. Further, the lower wafer W1 and the upper wafer W2 are respectively accommodated in the cassette C21 and the cassette C22 with their bonding surfaces W1ⱼ and W2ⱼ facing upwards.

The transfer section BN20 is provided adjacent to the positive X-axis side of the placing table BN10. Provided in this transfer section BN20 are a transfer path BN21 extending in the Y-axis direction and a transfer device BN22 configured to be movable along the transfer path BN21. The transfer device BN22 has a transfer arm configured to hold and transfer the lower wafer W1, the upper wafer W2, or the combined wafer T. The transfer arm is configured to be movable in horizontal directions and a vertical direction, and pivotable around a vertical axis. The transfer arm may be plural in number. The transfer arm transfers the upper wafer W2, the lower wafer W1, or the combined wafer T to a predetermined device adjacent to the transfer section BN20.

The number of the cassettes C21 to C23 placed on the placing table BN10 is not limited to the example shown in the drawings. In addition to the cassettes C21, C22 and C23, a cassette configured to collect a defective substrate, or the like may also be disposed on the placing table BN10.

The processing station BN3 is equipped with, for example, three processing blocks G11, G12 and G13. For example, the first processing block G11 is provided on the rear side (positive Y-axis direction of FIG. 14) of the processing station BN3, and the second processing block G12 is provided on the front side (negative Y-axis direction of FIG. 14) of the processing station BN3. Further, the third processing block G13 is provided on the carry-in/out station BN2 side (negative X-axis direction in FIG. 14) of the processing station BN3.

A transfer section BN60 is surrounded by the first to third processing blocks G11 to G13. A transfer device BN61 is disposed in the transfer section BN60. The transfer device BN61 has a transfer arm configured to hold and transfer the lower wafer W1, the upper wafer W2, or the combined wafer T. The transfer arm is configured to be movable in horizontal directions and a vertical direction, and pivotable around a vertical axis. The transfer arm may be plural in number. The transfer arm transfers the lower wafer W1, the upper wafer W2, or the combined wafer T to a predetermined device adjacent to the transfer section BN60.

The first processing block G11 is provided with, for example, an activation device BN33 and a hydrophilizing device BN34. The activation device BN33 is configured to modify the bonding surface W1ⱼ of the lower wafer W1 or the bonding surface W2ⱼ of the upper wafer W2 with plasma. The hydrophilizing device BN34 is configured to hydrophilize the modified bonding surface W1ⱼ of the lower wafer W1 or the modified bonding surface W2ⱼ of the upper wafer W2. The positions of the activation device BN33 and the hydrophilizing device BN34 are not limited to the example shown in the drawings. The activation device BN33 and the hydrophilizing device BN34 may be plural in number.

The activation device BN33 forms, for example, a dangling bond of Si by cutting a SiO2 bond in the bonding surfaces W1ⱼ and W2ⱼ and enables hydrophilization afterwards. In the activation device BN33, an oxygen gas as a processing gas is excited into plasma under, for example, a decompressed atmosphere to be ionized. As oxygen ions are radiated to the bonding surfaces W1j and W2j, the bonding surfaces W1ⱼ and W2ⱼ are modified by being plasma-processed. The processing gas is not limited to the oxygen gas, and may be, for example, a nitrogen gas, or the like.

The hydrophilizing device BN34 applies OH groups to, for example, the bonding surfaces W1ⱼ and W2j. The hydrophilizing device BN34 supplies pure water onto the lower wafer W1 or the upper wafer W2 while rotating the lower wafer W1 or the upper wafer W2 held by, for example, a spin chuck. The pure water is diffused on the bonding surface W1ⱼ or W2j, and imparts the OH groups to the dangling bond of Si and allows the bonding surface W1ⱼ or W2ⱼ to be hydrophilized. The hydrophilizing device BN34 also has a function of cleaning the bonding surfaces W1ⱼ and W2j.

The second processing block G12 is provided with, for example, a bonding device BN41. The bonding device BN41 inverts the upper wafer W2 and thus allows the bonding surface W2ⱼ of the upper wafer W2 to face downwards. Thereafter, the bonding device BN41 bonds the hydrophilized lower wafer W1 and the hydrophilized upper wafer W2 to manufacture the combined wafer T. Further, although a device configured to invert the upper wafer W2 is provided as a part of the bonding device BN41 in the present exemplary embodiment, it may be provided separately from the bonding device BN41.

The third processing block G13 is provided with, for example, a transition device BN51. The transition device BN51 temporarily stores therein the lower wafer W1, the upper wafer W2, or the combined wafer T. The transition device BN51 may be plural in number.

The bonding system BN1 is equipped with a control device BN90. The control device BN90 is, for example, a computer, and includes a calculator BN91, such as a CPU, and a storage BN92, such as a memory. The storage BN92 stores thereon a program for controlling various processing performed in the bonding system BN1. The control device BN90 causes the calculator BN91 to execute the program stored on the storage BN92 to control an operation of the bonding system BN1.

The annealing system AN1 includes a carry-in/out station AN2 and a processing station AN3. The carry-in/out station AN2 and the processing station AN3 are arranged in this order along the positive X-axis direction. The carry-in/out station AN2 and the processing station AN3 are connected as one body.

The carry-in/out station AN2 is equipped with a placing table AN10 and a transfer section AN20. The placing table AN10 includes a plurality of placing plates AN11. The cassettes C23 each of which accommodates therein a plurality of (e.g., 25) substrates horizontally are placed on the placing plates AN11, respectively. The cassette C23 accommodates therein the combined wafer T.

The transfer section AN20 is provided adjacent to the positive X-axis side of the placing table AN10. Provided in this transfer section AN20 are a transfer path AN21 extending in the Y-axis direction and a transfer device AN22 configured to be movable along this transfer path AN21. The transfer device AN22 has a transfer arm configured to hold and transfer the combined wafer T. The transfer arm is configured to be movable in horizontal directions and a vertical direction, and pivotable around a vertical axis. The transfer arm may be plural in number. The transfer arm transfers the combined wafer T to a predetermined device adjacent to the transfer section AN20.

The number of the cassettes C23 mounted on the placing table AN10 is not limited to the example shown in the drawings. In addition to the cassettes C23, a cassette configured to collect a defective substrate, or the like may also be disposed on the placing table AN10.

The processing station AN3 is equipped with, for example, three processing blocks G21, G22 and G23. For example, the first processing block G21 is provided on the rear side (positive Y-axis direction of FIG. 14) of the processing station AN3, and the second processing block G22 is provided on the front side (negative Y-axis direction of FIG. 14) of the processing station AN3. Further, the third processing block G23 is provided on the carry-in/out station AN2 side (negative X-axis direction in FIG. 14) of the processing station AN3.

A transfer section AN60 is surrounded by the first to third processing blocks G21 to G23. A transfer device AN61 is disposed in the transfer section AN60. The transfer device AN61 has a transfer arm configured to hold and transfer the combined wafer T. The transfer arm is configured to be movable in horizontal directions and a vertical direction, and pivotable around a vertical axis. The transfer arm may be plural in number. The transfer arm transfers the combined wafer T to a predetermined device adjacent to the transfer section AN60.

The first processing block G21 is provided with, for example, an annealing device AN43 and an annealing device AN44. The annealing device AN43 performs heat treatment on the combined wafer T. Before the heat treatment, the lower wafer W1 is bonded to the upper wafer W2 by a hydrogen bond between OH groups. The heat treatment causes a dehydration condensation reaction, and a covalent bond is formed by the dehydration condensation reaction.

Thus, bonding strength between the lower wafer W1 and the upper wafer W2 is enhanced. A plurality of annealing devices AN43 is stacked in, for example, Z-axis direction. The plurality of annealing devices AN43 is configured to perform heat treatment on the combined wafer T at different set temperatures from each other. The plurality of annealing devices AN43 includes an annealing device whose set temperature is equal to a target temperature, and an annealing device whose set temperature is in a first temperature range which is lower than the target temperature. The target temperature refers to a temperature at which the dehydration condensation reaction occurs and the covalent bond is formed. The target temperature is, for example, 350° C. or more. In the present exemplary embodiment, the plurality of annealing device AN43 includes five annealing devices AN43a to AN43e. The annealing devices AN43a, AN43b, AN43c, AN43d and AN43e have set temperatures of 50° C., 100° C., 150° C., 200° C. and 350° C. (target temperature), respectively. The number of the annealing devices AN43 is not limited to the example shown in the drawings. The annealing device AN44 may have the same configuration as the annealing device AN43. The annealing device AN44 includes five annealing devices AN44a to AN44e. The annealing device AN44 enables a plurality of combined wafers T to be heat-treated at the same time. The annealing device AN44 may be omitted.

The second processing block G22 is provided with, for example, an annealing device AN45 and an annealing device AN46. Each of the annealing device AN45 and the annealing device AN46 may have the same configuration as the annealing device AN43. The annealing device AN45 includes five annealing devices AN45a to AN45e. Also, the annealing device AN46 includes five annealing devices AN46a to AN46e. Each of the annealing device AN45 and the annealing device AN46 enables a plurality of combined wafers T to be heat-treated at the same time. The annealing device AN45 and the annealing device AN46 may be omitted.

The third processing block G23 is provided with, for example, a transition device AN51. The transition device AN51 temporarily stores therein the combined wafer T. The transition device AN51 may be plural in number.

The annealing system AN1 is equipped with a control device AN90. The control device AN90 is, for example, a computer, and includes a calculator AN91, such as a CPU, and a storage AN92, such as a memory. The storage AN92 stores thereon a program for controlling various processing performed in the annealing system AN1. The control device AN90 causes the calculator AN91 to execute the program stored on the storage AN92 to control an operation of the annealing system AN1.

### (Bonding Method)

Referring to FIG. 16, a bonding method according to the second exemplary embodiment will be described. The processing shown in FIG. 16 is performed under the control of the control device BN90 or AN90.

First, the cassette C21 which accommodates therein a plurality of lower wafers W1, the cassette C22 which accommodates therein a plurality of upper wafers W2, and the empty cassette C23 are placed on the placing table BN10 of the carry-in/out station BN2.

Then, the transfer device BN22 takes out the lower wafer W1 from the cassette C1, and transfers it to the transition device BN51. Then, the transfer device BN61 takes out the lower wafer W1 from the transition device BN51, and transfers it to the activation device BN33.

Thereafter, the activation device BN33 modifies the bonding surface W1ⱼ of the lower wafer W1 (process S201). The bonding surface W1ⱼ is modified in a state where the bonding surface W1ⱼ faces upwards. Then, the transfer device BN61 takes out the lower wafer W1 from the activation device BN33, and transfers it to the hydrophilizing device BN34.

Thereafter, the hydrophilizing device BN34 hydrophilizes the bonding surface W1j of the lower wafer W1 (process S202). The bonding surface W1ⱼ is hydrophilized in a state where the bonding surface W1ⱼ faces upwards. Then, the transfer device BN61 takes out the lower wafer W1 from the hydrophilizing device BN34, and transfers it to the bonding device BN41.

The above-described processing on the lower wafer W1 are performed in parallel with the following processing on the upper wafer W2. First, the transfer device BN22 takes out the upper wafer W2 from the cassette C22, and transfers it to the transition device BN51. Then, the transfer device BN61 takes out the upper wafer W2 from the transition device BN51, and transfers it to the activation device BN33.

Then, the activation device BN33 modifies the bonding surface W2ⱼ of the upper wafer W2 (process S203). The bonding surface W2ⱼ is modified in a state where the bonding surface W2ⱼ faces upwards. Then, the transfer device BN61 takes out the upper wafer W2 from the activation device BN33, and transfers it to the hydrophilizing device BN34.

Thereafter, the hydrophilizing device BN34 hydrophilizes the bonding surface W2j of the upper wafer W2 (process S204). The bonding surface W2ⱼ is hydrophilized in a state where the bonding surface W2ⱼ faces upwards. Then, the transfer device BN61 takes out the upper wafer W2 from the hydrophilizing device BN34, and transfers it to the bonding device BN41.

Thereafter, the bonding device BN41 inverts the upper wafer W2 and thus allows the bonding surface W2ⱼ of the upper wafer W2 to face downwards. Then, the bonding device BN41 bonds the lower wafer W1 and the upper wafer W2 to manufacture the combined wafer T (process S205). Thereafter, the transfer device BN61 takes out the combined wafer T from the bonding device BN41, and transfers it to the transition device BN51.

Then, the transfer device BN22 takes out the combined wafer T from the transition device BN51, and transfers it to the cassette C23 on the placing table BN10. Thereafter, a non-illustrated transfer device transfers the cassette C23 on the placing table BN10 to the placing table AN10 of the annealing system AN1.

Then, the transfer device AN22 takes out the combined wafer T from the cassette C23, and transfers it to the transition device AN51. Thereafter, the transfer device AN61 takes out the combined wafer T from the transition device AN51, and transfers it to the annealing device AN43.

Then, the annealing device AN43 performs the heat treatment on the combined wafer T (process S206). Thereafter, the bonding strength between the lower wafer W1 and the upper wafer W2 is enhanced. The heat treatment will be described in detail below. Then, the transfer device AN61 takes out the combined wafer T from the annealing device AN43, and transfers it to the transition device AN51.

Thereafter, the transfer device AN22 takes out the combined wafer T from the transition device AN51, and transfers it to the cassette C23 on the placing table AN10. Thus, a series of processing are completed.

### (Bonding Device)

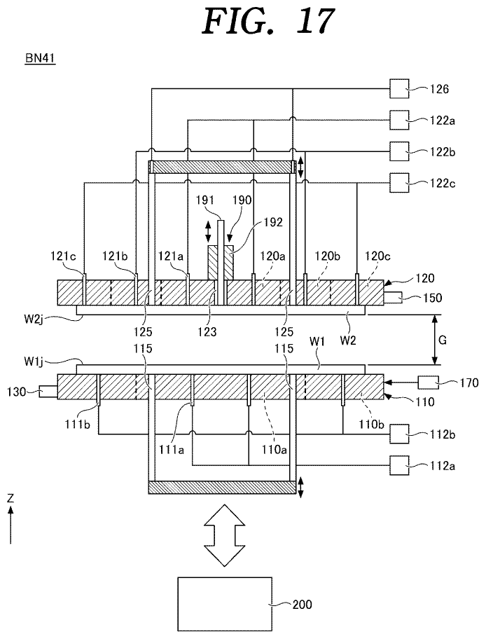

Referring to FIG. 17, an example of the bonding device BN41 will be described. The bonding device BN41 is equipped with a lower holder 110, an upper holder 120, a lower imaging device 130, an upper imaging device 150, a moving mechanism 170, and a controller 200.

The lower holder 110 is configured to hold the lower wafer W1 from below with the bonding surface W1ⱼ of the lower wafer W1 facing upwards. The upper holder 120 is configured to hold the upper wafer W2 from above with the bonding surface W2ⱼ of the upper wafer W2 facing downwards.

The lower imaging device 130 is provided at the lower holder 110 and configured to image the upper wafer W2 held by the upper holder 120. The upper imaging device 150 is provided at the upper holder 120 and configured to image the lower wafer W1 held by the lower holder 110.

The moving mechanism 170 is configured to move the lower holder 110 and the upper holder 120 relative to each other in a horizontal direction and a vertical direction. Although the moving mechanism 170 moves the lower holder 110 in the present exemplary embodiment, it may move the upper holder 120 instead. Further, the moving mechanism 170 may rotate the lower holder 110 or the upper holder 120 around a vertical axis.

The controller 200 controls an operation of the bonding device BN41. The controller 200 is, for example, a computer and has the same configuration as the control device BN90. The controller 200 may be a part of the control device BN90.

The lower holder 110 is divided into a plurality of (e.g., two) regions 110a and 110b. These regions 110a and 110b are provided in this order from the center of the lower holder 110 toward the periphery thereof. The region 110a has a circular shape when viewed from the top, and the region 110b has an annular shape when viewed from the top.

Suction pipes 111a and 111b are independently provided in the regions 110a and 110b, respectively. Separate vacuum pumps 112a and 112b are connected to the suction pipes 111a and 111b, respectively. The lower holder 110 can vacuum-adsorb the lower wafer W1 in each of the regions 110a and 110b.

The lower holder 110 is provided with a plurality of holding pins 115 configured to be movable up and down in the vertical direction. The lower wafer W1 is placed on upper ends of the plurality of holding pins 115. The lower wafer W1 may be vacuum-adsorbed to the upper ends of the plurality of holding pins 115.

The plurality of holding pins 115 is protruded from a holding surface of the lower holder 110 as they are raised. In this state, the plurality of holding pins 115 receives the lower wafer W1 from the transfer device BN61. Then, the plurality of holding pins 115 is lowered, and, thus, the lower wafer W1 comes into contact with the holding surface of the lower holder 110. Thereafter, the lower holder 110 horizontally vacuum-adsorbs the lower wafer W1 in each of the regions 110a and 110b by operations of the vacuum pumps 112a and 112b, respectively.

The upper holder 120 is divided into a plurality of (e.g., three) regions 120a, 120b, and 120c. These regions 120a, 120b and 120c are provided in this order from the center of the upper holder 120 toward the periphery thereof. The region 120a has a circular shape when viewed from the top, and each of the regions 120b and 120c have an annular shape when viewed from the top.

Suction pipes 121a, 121b and 121c are independently provided in the regions 120a, 120b and 120c, respectively. Separate vacuum pumps 122a, 122b and 122c are connected to the suction pipes 121a, 121b and 121c, respectively. The upper holder 120 can vacuum-adsorb the upper wafer W2 in each of the regions 120a, 120b and 120c.

The upper holder 120 is provided with a plurality of holding pins 125 configured to be movable up and down in the vertical direction. The plurality of holding pins 125 is connected to a vacuum pump 126 to vacuum-adsorb the upper wafer W2 by an operation of the vacuum pump 126. The upper wafer W2 is vacuum-adsorbed to lower ends of the plurality of holding pins 125. Instead of the plurality of holding pins 125, a ring-shaped attraction pad may be used.

The plurality of holding pins 125 is protruded from a holding surface of the upper holder 120 when they are lowered. In this state, the plurality of holding pins 125 receives the upper wafer W2 from the transfer device BN61 by vacuum-adsorbing the upper wafer W2. Thereafter, the plurality of holding pins 125 is raised, and, thus, the upper wafer W2 comes into contact with the holding surface of the upper holder 120. Then, the upper holder 120 horizontally vacuum-adsorbs the upper wafer W2 in each of the regions 120a, 120b and 120c by operations of the vacuum pumps 122a, 122b and 122c, respectively.

Further, a through hole 123 is formed through the center of the upper holder 120 in the vertical direction. A pushing device 190 to be described later is inserted through the through hole 123. The pushing device 190 is configured to press the center of the upper wafer W2 spaced apart from the lower wafer W1 to bring the upper wafer W2 into contact with the lower wafer W1.

The pushing device 190 has a push pin 191 and an outer cylinder 192 serving as an elevation guide for the push pin 191. The push pin 191 is inserted through the through hole 123 by, for example, a driver (not shown) having a motor therein, and is protruded from the holding surface of the upper holder 120 and presses the center of the upper wafer W2.

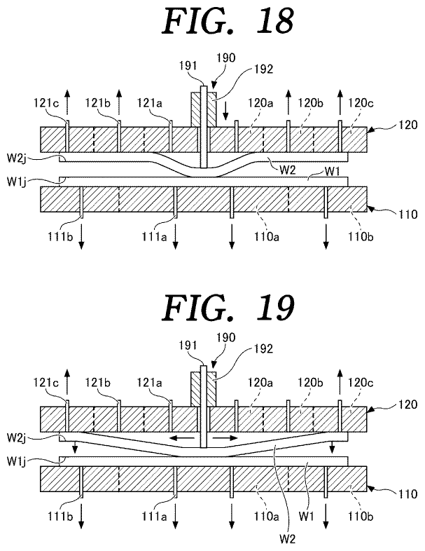

Hereinafter, referring to FIG. 18 to FIG. 20, an example of an operation of the bonding device BN41 will be described. First, the transfer device BN61 carries the lower wafer W1 and the upper wafer W2 into the bonding device BN41. The lower holder 110 holds the lower wafer W1 from below with the bonding surface W1ⱼ of the lower wafer W1 facing upwards. The upper holder 120 holds the upper wafer W2 from above with the bonding surface W2ⱼ of the upper wafer W2 facing downwards.

Then, the moving mechanism 170 moves the lower holder 110 and the upper holder 120 relative to each other to perform the position alignment of the lower wafer W1 and the upper wafer W2. For the position alignment, the lower imaging device 130 and the upper imaging device 150 are used as shown in FIG. 17. The upper imaging device 150 is fixed to the upper holder 120, and serves to image the bonding surface W1ⱼ of the lower wafer W1 held by the lower holder 110. Meanwhile, the lower imaging device 130 is fixed to the lower holder 110, and serves to image the bonding surface W2ⱼ of the upper wafer W2 held by the upper holder 120.

Thereafter, as shown in FIG. 18, when the operation of the vacuum pump 122a is stopped, the vacuum adsorption of the upper wafer W2 in the region 120a is released. Then, the push pin 191 of the pushing device 190 is lowered and presses the center of the upper wafer W2 into contact with the lower wafer W1. As a result, the centers of the lower wafer W1 and the upper wafer W2 are bonded to each other.

Since the bonding surface W1ⱼ of the lower wafer W1 and the bonding surface W2j of the upper wafer W2 have been modified, a van der Waals force (intermolecular force) is generated between the bonding surfaces W1ⱼ and W2j, and, thus, the bonding surfaces W1ⱼ and W2j are bonded to each other. Also, since the bonding surfaces W1ⱼ and W2ⱼ have been hydrophilized, hydrophilic groups (e.g., OH groups) are hydrogen-bonded, and, thus, the bonding surfaces W1ⱼ and W2ⱼ are firmly bonded to each other.

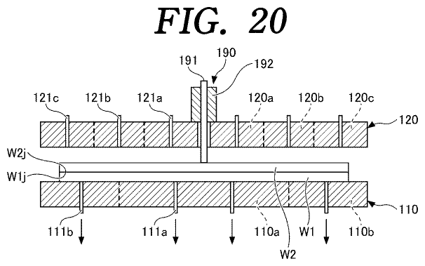

Then, as shown in FIG. 19, when the operation of the vacuum pump 122b is stopped, the vacuum adsorption of the upper wafer W2 in the region 120b is released. Thereafter, when the operation of the vacuum pump 122c is stopped, the vacuum adsorption of the upper wafer W2 in the region 120c is released as shown in FIG. 20.

As described above, the vacuum adsorption of the upper wafer W2 is released step by step from the center to the periphery of the upper wafer W2. Thus, the upper wafer W2 falls down into contact with the lower wafer W1 step by step. Then, the bonding of the lower wafer W1 and the upper wafer W2 progresses sequentially from the centers toward the peripheries thereof. As a result, the entire bonding surface W2ⱼ of the upper wafer W2 and the entire bonding surface W1ⱼ of the lower wafer W1 come into contact with each other, and, thus, the lower wafer W1 and the upper wafer W2 are bonded to each other, so that the combined wafer T is obtained. Thereafter, the push pin 191 is raised up to its original position.

Then, the moving mechanism 170 lowers the lower holder 110 to widen the distance between the lower holder 110 and the upper holder 120 in the vertical direction. Thereafter, the transfer device BN61 carries out the combined wafer T from the bonding device BN41. Specifically, the lower holder 110 first releases the holding of the combined wafer T. Then, the plurality of holding pins 115 is raised to transfer the combined wafer T to the transfer device BN61. Thereafter, the plurality of holding pins 115 is lowered back to their original positions.

### (Heat Treatment)

The heat treatment (process S206) of the bonding method according to the second exemplary embodiment will be described in detail.

In the process S206, the combined wafer T is heat-treated in the first temperature range, which is lower than the predetermined target temperature, before being heat-treated at the target temperature. A reaction rate of the dehydration condensation reaction decreases as the temperature decreases. Since the combined wafer T is heat-treated in the first temperature range, which is lower than the target temperature, before being heat-treated at the target temperature, a temperature rising rate of the combined wafer T becomes gentle. Therefore, it is possible to suppress the H2O generation amount by the dehydration condensation reaction from exceeding the H2O absorption amount by the oxidation reaction. As a result, it is possible to suppress H2O from remaining on the bonding surface between the lower wafer W1 and the upper wafer W2 and thus possible to suppress a decrease in bonding strength between the lower wafer W1 and the upper wafer W2.

The target temperature refers to a temperature at which the dehydration condensation reaction occurs and the covalent bond is formed. The target temperature is, for example, 350° C. or more.

The heat treatment in the first temperature range may include maintaining an atmosphere in which the combined wafer T is provided in a temperature range of 100° C. to less than 150° C. In the temperature range of 100° C. to less than 150° C., the dehydration reaction is caused by evaporation of water. For this reason, the atmosphere in which the combined wafer T is provided is maintained in the temperature range of 100° C. to less than 150° to cause the dehydration reaction by the evaporation of water. Thus, H2O may be produced before the atmosphere in which the combined wafer T is provided reaches the target temperature. As a result, it is possible to suppress a sharp increase in the H2O generation amount when the combined wafer T is heat-treated at the target temperature, and, thus, it is possible to suppress the H2O generation amount from exceeding the H2O absorption amount. The atmosphere in which the combined wafer T is provided may be maintained in the temperature range of 100° C. to less than 150° for a longer period of time, e.g., 5 minutes, for which the temperature of the combined wafer T reaches the temperature range of 100° C. to less than 150°.

The heat treatment in the first temperature range may include maintaining the atmosphere in which the combined wafer T is provided in a temperature range of 300° C. to less than 350° C. In the temperature range of 300° C. to less than 350° C., the dehydration reaction is caused by removal of adsorption water. For this reason, the atmosphere in which the combined wafer T is provided is maintained in the temperature range of 300° C. to less than 350° to cause the dehydration reaction by the removal of adsorption water. Thus, H2O may be produced before the atmosphere in which the combined wafer T is provided reaches the target temperature. As a result, it is possible to suppress the sharp increase in the H2O generation amount when the combined wafer T is heat-treated at the target temperature, and, thus, it is possible to suppress the H2O generation amount from exceeding the H2O absorption amount. The atmosphere in which the combined wafer T is provided may be maintained in the temperature range of 300° C. to less than 350° for a longer period of time, e.g., 5 minutes, for which the temperature of the combined wafer T reaches the temperature range of 300° C. to less than 350°.

Hereinafter, an example method of performing the heat treatment on the combined wafer T in the annealing device AN43 will be described. The annealing device AN43 includes the five annealing devices AN43a to AN43e.

First, the annealing device AN43a performs heat treatment on the combined wafer T. A set temperature of the annealing device AN43a is 50° C. For this reason, the combined wafer T is heat-treated in an atmosphere of 50° C. The annealing device AN43a performs the heat treatment on the combined wafer T for, e.g., 5 minutes. Then, the transfer device AN61 takes out the combined wafer T from the annealing device AN43a, and transfers it to the annealing device AN43b.

Thereafter, the annealing device AN43b performs heat treatment on the combined wafer T. A set temperature of the annealing device AN43b is 100° C. For this reason, the combined wafer T is heat-treated in an atmosphere of 100° C. The annealing device AN43b performs the heat treatment on the combined wafer T for, e.g., 5 minutes. Then, the transfer device AN61 takes out the combined wafer T from the annealing device AN43b, and transfers it to the annealing device AN43c.

Thereafter, the annealing device AN43c performs heat treatment on the combined wafer T. A set temperature of the annealing device AN43c is 150° C. For this reason, the combined wafer T is heat-treated in an atmosphere of 150° C. The annealing device AN43c performs the heat treatment on the combined wafer T for, e.g., 5 minutes. Then, the transfer device AN61 takes out the combined wafer T from the annealing device AN43c, and transfers it to the annealing device AN43d.

Thereafter, the annealing device AN43d performs heat treatment on the combined wafer T. A set temperature of the annealing device AN43d is 200° C. For this reason, the combined wafer T is heat-treated in an atmosphere of 200° C. The annealing device AN43d performs the heat treatment on the combined wafer T for, e.g., 5 minutes. Then, the transfer device AN61 takes out the combined wafer T from the annealing device AN43d, and transfers it to the annealing device AN43e.

Thereafter, the annealing device AN43e performs heat treatment on the combined wafer T. A set temperature of the annealing device AN43e is 350° C. (target temperature). For this reason, the combined wafer T is heat-treated in an atmosphere of 350° C. Thus, the bonding strength between the lower wafer W1 and the upper wafer W2 is enhanced. The annealing device AN43e performs the heat treatment on the combined wafer T for, e.g., 60 minutes. Then, the transfer device AN61 takes out the combined wafer T from the annealing device AN43e, and transfers it to the transition device AN51. Finally, the transfer device AN22 takes out the combined wafer T from the transition device AN51, and accommodates it in the cassette C23. The combined wafer T being accommodated in the cassette C23 carried out of the annealing system AN1.

As described above, according to the second exemplary embodiment, the combined wafer T is transferred to the five annealing devices AN43a to AN43e in this order. Thus, as shown in FIG. 12, the temperature of the atmosphere in which the combined wafer T is provided can be increased in the stepwise manner. In this case, during the heat treatment in the process S206, the temperature rising rate of the combined wafer T becomes gentle. Therefore, it is possible to suppress the H2O generation amount by the dehydration condensation reaction from exceeding the

H2O absorption amount by the oxidation reaction. As a result, it is possible to suppress H2O from remaining on the bonding surface between the lower wafer W1 and the upper wafer W2 and thus possible to suppress the decrease in bonding strength between the lower wafer W1 and the upper wafer W2. Also, during the heat treatment, the set temperatures of the respective annealing devices AN43a to AN43e are not changed. For this reason, time required for increasing the temperatures of the respective annealing devices AN43a to AN43e is not necessary. Further, it is possible to reduce the power consumption of the annealing devices AN43a to AN43e.

The H2O generation amount during the heat treatment varies depending on a difference in type of a film to be bonded, activation conditions of the bonding surfaces W1ⱼ and W2j, hydrophilization conditions of the bonding surfaces W1ⱼ and W2j, and a waiting time from a time point when the bonding in the process S205 is ended to a time point when the heat treatment in the process S206 is started. Therefore, it is desirable to determine temperature rising conditions during the heat treatment depending on the difference in type of a film to be bonded, the activation conditions of the bonding surfaces W1ⱼ and W2j, the hydrophilization conditions of the bonding surfaces W1ⱼ and W2j, and the waiting time. In this case, it is possible to suppress H2O from remaining on the bonding surface between the lower wafer W1 and the upper wafer W2 and also possible to reduce the time required for the heat treatment. The temperature rising conditions include, for example, time required for performing the heat treatment on the combined wafer T in each of the annealing devices AN43a to AN43e. The temperature rising conditions may include the set temperatures of the respective annealing devices AN43a to AN43e.

Also, in the second exemplary embodiment, it has been described that the combined wafer T is transferred to the five annealing devices AN43a to AN43e in this order. However, the present disclosure is not limited thereto. For example, the set temperature of one annealing device AN43 may be changed to increase the temperature of the atmosphere in which the combined wafer T is provided in the stepwise manner.

Further, in the second exemplary embodiment, it has been described that the temperature of the atmosphere in which the combined wafer T is provided is increased in the stepwise manner. However, the present disclosure is not limited thereto. For example, as shown in FIG. 13, the temperature of the atmosphere in which the combined wafer T is provided may be continuously increased from the room temperature to the target temperature. In this case, it is desirable to increase the set temperature from the room temperature to the target temperature at a temperature rising rate of 10° C./min or less. Thus, it is possible to suppress the H2O generation amount from exceeding the H2O absorption amount regardless of the type of a film to be bonded. Therefore, it becomes easy to suppress H2O from remaining on the bonding surface between the lower wafer W1 and the upper wafer W2.

Furthermore, in the second exemplary embodiment, it has been described that the annealing system AN1 is provided separately from the bonding system BN1. However, the present disclosure is not limited thereto. For example, the bonding system BN1 may be equipped with the annealing device AN43.

The exemplary embodiments disclosed herein are illustrative in all aspects and do not limit the present disclosure. The above-described exemplary embodiments may be omitted, substituted, or changed in various forms without departing from the scope and spirit of the appended claims.

According to the present disclosure, it is possible to suppress a decrease in bonding strength.

From the foregoing, it will be appreciated that various exemplary embodiments of the present disclosure have been described herein for purposes of illustration and various changes can be made without departing from the scope and spirit of the present disclosure. Accordingly, various exemplary embodiments described herein are not intended to be limiting, and the true scope and spirit are indicated by the following claims.

We claim:

1. A bonding method, comprising:
preparing a first semiconductor substrate having a first surface and a second semiconductor substrate having a second surface;
hydrophilizing the first surface of the first semiconductor substrate and the second surface of the second semiconductor substrate;
bonding the first surface of the first semiconductor substrate and the second surface of the second semiconductor substrate after the hydrophilizing; and
enhancing bonding strength between the first semiconductor substrate and the second semiconductor substrate by performing heat treatment on the first semiconductor substrate and the second semiconductor substrate after the bonding,
wherein the enhancing of the bonding strength includes:
performing heat treatment on the first semiconductor substrate and the second semiconductor substrate in a first temperature range; and
performing heat treatment on the first semiconductor substrate and the second semiconductor substrate at a target temperature after the performing of the heat treatment in the first temperature range, and
the first temperature range is lower than the target temperature.

2. The bonding method of claim 1,
wherein the target temperature is 350° C. or more.

3. The bonding method of claim 1,
wherein the performing of the heat treatment in the first temperature range includes increasing a temperature of an atmosphere in which the first semiconductor substrate and the second semiconductor substrate are provided in a stepwise manner.

4. The bonding method of claim 3,
wherein the performing of the heat treatment in the first temperature range includes maintaining the temperature of the atmosphere in a temperature range equal to or larger than 100° C. and smaller than 150° C.

5. The bonding method of claim 3,
wherein the performing of the heat treatment in the first temperature range includes maintaining the temperature of the atmosphere in a temperature range equal to or larger than 300° C. and smaller than 350° C.

6. The bonding method of claim 3,
wherein the performing of the heat treatment in the first temperature range includes sequentially annealing the first semiconductor substrate and the second semiconductor substrate via multiple annealing devices whose set temperatures are different from each other.

7. The bonding method of claim 1,
wherein the performing of the heat treatment in the first temperature range includes continuously increasing a temperature of an atmosphere in which the first semiconductor substrate and the second semiconductor substrate are provided.

8. The bonding method of claim 7,
wherein the performing of the heat treatment in the first temperature range includes accommodating the first semiconductor substrate and the second semiconductor substrate in an annealing device and increasing a set temperature of the annealing device to the target temperature at a temperature rising rate of 10° C./min or less.

9. The bonding method of claim 1,
wherein the first semiconductor substrate is a semiconductor wafer, and
the second semiconductor substrate is a semiconductor wafer.

10. The bonding method of claim 1,
wherein the first semiconductor substrate is a semiconductor wafer, and
the second semiconductor substrate is a die.

11. A bonding system, comprising:
a first hydrophilizing device configured to hydrophilize a first surface of a first semiconductor substrate;
a second hydrophilizing device configured to hydrophilize a second surface of a second semiconductor substrate;
a bonding device configured to bond the first surface of the first semiconductor substrate and the second surface of the second semiconductor substrate; and
an annealing device configured to perform heat treatment on the first semiconductor substrate and the second semiconductor substrate to enhance bonding strength between the first semiconductor substrate and the second semiconductor substrate,
wherein the annealing device is configured to:
perform heat treatment on the first semiconductor substrate and the second semiconductor substrate in a first temperature range; and
perform heat treatment on the first semiconductor substrate and the second semiconductor substrate at a target temperature after performing the heat treatment in the first temperature range, and
the first temperature range is lower than the target temperature.

12. The bonding system of claim 11,
wherein the annealing device includes:
a first annealing device configured to perform the heat treatment in the first temperature range; and
a second annealing device provided separately from the first annealing device and configured to perform the heat treatment at the target temperature.

13. The bonding system of claim 12, further comprising:
a substrate transfer arm configured to transfer the first semiconductor substrate and the second semiconductor substrate between the first annealing device and the second annealing device.

14. A bonding system, comprising:
a first activation device configured to activate a bonding surface of a first semiconductor substrate;
a first hydrophilizing device configured to hydrophilize the bonding surface of the first semiconductor substrate, the first semiconductor substrate including a base substrate and a semiconductor element, a circuit or a terminal disposed on the base substrate;
a second activation device configured to activate a bonding surface of a second semiconductor substrate;
a second hydrophilizing device configured to hydrophilize the bonding surface of the second semiconductor substrate, the second semiconductor substrate including a base substrate and a plurality of semiconductor elements, circuits or terminals disposed on the base substrate;
a bonding device configured to detach the first semiconductor substrate from a second die carrier and position the bonding surface of the first semiconductor substrate to face the bonding surface of the second semiconductor substrate; and
an annealing device configured to perform heat treatment on the first semiconductor substrate and the second semiconductor substrate at multiple temperature ranges to enhance bonding strength between the first semiconductor substrate and the second semiconductor substrate.

15. The bonding system of claim 14,
wherein the annealing device includes:
a first annealing device configured to perform the heat treatment in the first temperature range; and
a second annealing device provided separately from the first annealing device and configured to perform the heat treatment at the target temperature.

16. The bonding system of claim 14, further comprising:
a substrate transfer arm configured to transfer the first semiconductor substrate and the second semiconductor substrate between the first annealing device and the second annealing device.

17. The bonding method of claim 14,
wherein the performing of the heat treatment in the first temperature range includes increasing a temperature of an atmosphere in which the first semiconductor substrate and the second semiconductor substrate are provided in a stepwise manner.

18. The bonding system of claim 14, wherein the bonding device includes:
a first die carrier holder configured to hold a first die carrier;
a pressing device;
a second die carrier holder configured to hold the second die carrier; and
a die transfer mechanism configured to transfer the first semiconductor substrate from the first die carrier to the second die carrier, the die transfer mechanism including an adsorption head configured to adsorb the first semiconductor substrate.

19. The bonding system of claim 18, wherein the first die carrier includes tape to which the first semiconductor substrate is attached, and
the pressing device is configured to press the first semiconductor substrate via the tape to locally deform the tape.

20. The bonding system of claim 19, wherein the second die carrier holder is configured to hold the second die carrier from above the second die carrier, and
the bonding device further includes a substrate holder configured to hold the second semiconductor device from below the second semiconductor device.
